(19) United States
(12) Patent Application Publication
(10) Pub. No.: US 2025/0379091 A1
(43) Pub. Date: Dec. 11, 2025

(54) MANUFACTURING METHOD FOR SEMICONDUCTOR USING WARPAGE COMPENSATION WAFER AND MANUFACTURING METHOD FOR WARPAGE COMPENSATION WAFER

(71) Applicant: Samsung Electronics Co., Ltd., Suwon-si (KR)

(72) Inventors: Jinyoung Lee, Suwon-si (KR); Sunghyup Kim, Suwon-si (KR); Injae Lee, Suwon-si (KR); Sukwon Lee, Suwon-si (KR)

(21) Appl. No.: 18/958,030

(22) Filed: Nov. 25, 2024

(30) Foreign Application Priority Data
Jun. 10, 2024 (KR) 10-2024-0075216

(51) Int. Cl. H01L 21/683; H01L 21/66

(52) U.S. Cl. CPC H01L 21/6835; H01L 22/12

(57) ABSTRACT

A semiconductor manufacturing method according to some embodiments of the present disclosure may use at least one warpage compensation wafer. The at least one warpage compensation wafer may include a first warpage compensation wafer. The first warpage compensation wafer may include a first base layer having a flat bottom surface, a first reinforcement structure on a top surface of the first base layer, and a first temporary layer stacked on the first base layer and the first reinforcement structure. The semiconductor manufacturing method may include chucking a bottom surface of the first warpage compensation wafer, performing a first semiconductor manufacturing process directly on a top surface of the first temporary layer, and separating the first warpage compensation wafer.

### CROSS-REFERENCE TO RELATED APPLICATION(S)

This application claims the benefit of Korean Patent Application No. 10-2024-0075216, filed on Jun. 10, 2024 in the Korean Intellectual Property Office, the disclosure of which is incorporated herein by reference in its entirety.

### FIELD

The present disclosure relates to a method of manufacturing a semiconductor using a warpage compensation wafer and a method of manufacturing the warpage compensation wafer.

### BACKGROUND

There may be an issue of warpage arising due to thermal and/or mechanical stress in processes of manufacturing semiconductor dies or packages. Such a semiconductor warpage may significantly impact the reliability and performance of semiconductor products. The semiconductor warpage may also lead to mechanical failures including, for example, cracking and delamination, and the degradation of device characteristics. Additionally, the semiconductor warpage that exceeds an equipment tolerance may hinder the progress of the processes.

### SUMMARY

An aspect of the present disclosure is to provide a method to reduce warpage that may occur in a semiconductor manufacturing process.

Another aspect of the present disclosure is to provide a warpage compensation wafer that facilitates chucking and a method of manufacturing the warpage compensation wafer.

Another aspect of the present disclosure is to provide a method of using a warpage compensation wafer suitable for each type of warpage in each semiconductor manufacturing process.

Another aspect of the present disclosure is to provide a method of reusing a warpage compensation wafer that has been used to reduce warpage.

Another aspect of the present disclosure is to provide a reusable warpage compensation wafer and a method of manufacturing the reusable warpage compensation wafer.

Additional aspects of embodiments will be apparent from the description which follows, or may be learned by practice of the disclosure.

According to some embodiments of the present disclosure, a semiconductor manufacturing method may use at least one warpage compensation wafer. The at least one warpage compensation wafer may include a first warpage compensation wafer. The first warpage compensation wafer may include a first base layer having a flat bottom surface, a first reinforcement structure on a top surface of the first base layer, and a first temporary layer stacked on the first base layer and on the first reinforcement structure. The semiconductor manufacturing method may include chucking a bottom surface of the first warpage compensation wafer, performing a first semiconductor manufacturing process directly on a top surface of the first temporary layer, and separating the first warpage compensation wafer.

According to some embodiments of the present disclosure, a semiconductor manufacturing method may use a warpage compensation wafer. The warpage compensation wafer may include a base layer having a flat bottom surface, a reinforcement structure on a top surface of the base layer, and a temporary layer stacked on the base layer and on the reinforcement structure. The semiconductor manufacturing method may include chucking a bottom surface of the warpage compensation wafer, bonding a semi-finished semiconductor product to a top surface of the temporary layer, performing a semiconductor manufacturing process directly on a top surface of the semi-finished semiconductor product, and separating the semi-finished semiconductor product and the warpage compensation wafer.

According to some embodiments of the present disclosure, a method of manufacturing a warpage compensation wafer may include installing a reinforcement structure on a top surface of a base layer having a flat bottom surface to be chucked on a wafer chuck, wherein the reinforcement structure has a material with a stiffness greater than that of a material of the base layer, stacking a temporary layer covering at least a portion of a top of the base layer and a top of the reinforcement structure, and planarizing a top surface of the temporary layer.

According to the present disclosure, a warpage compensation wafer may be used to reduce warpage, thereby reducing the negative effects of warpage and improving the reliability of a resulting process product.

According to the present disclosure, a reinforcement structure may be provided in a shape embedded in a temporary layer rather than in a bottom surface of a warpage compensation wafer. This may enable the bottom surface of the warpage compensation wafer to be flat, facilitating chucking of the warpage compensation wafer. Additionally, a top surface of the warpage compensation wafer may also be formed to be flat, enabling a semiconductor manufacturing process (e.g., a deposition process) to be performed directly on the top surface of the warpage compensation wafer.

According to the present disclosure, semiconductor manufacturing processes may be performed using different warpage compensation wafers according to different types of warpage that may occur in the respective semiconductor manufacturing processes, thereby improving the quality of a resulting process product from each process.

According to the present disclosure, some remaining portions (e.g., a reinforcement structure and a base layer) of a warpage compensation wafer, other than a temporary layer, may be reusable, reducing the overall semiconductor manufacturing cost and time.

The effects that can be achieved by the various example embodiments of the present disclosure are not limited to those described above, and other effects not described above can also be clearly derived and understood by a person having ordinary skill in the art to which the present disclosure pertains from the following description. That is, unintended effects of practicing the embodiments of the present disclosure can also be derived by a person having ordinary skill in the art based on the example embodiments of the present disclosure.

### BRIEF DESCRIPTION OF THE DRAWINGS

These and/or other aspects, features, and advantages of the present disclosure will become apparent and more readily appreciated from the following description of example embodiments, taken in conjunction with the accompanying drawings of which:

FIG. 1 is a perspective view of a warpage compensation wafer according to some embodiments of the present disclosure;

FIG. 2 is a top view of a warpage compensation wafer according to some embodiments of the present disclosure;

FIG. 3 is a cross-sectional view of a warpage compensation wafer, taken along cutting line I-I of FIG. 2;

FIG. 4 is a diagram illustrating an example warpage type;

FIG. 5 is a cross-sectional view of a semi-finished semiconductor product formed on a top surface of a warpage compensation wafer according to some embodiments of the present disclosure;

FIG. 6 is a top view of a warpage compensation wafer according to some embodiments of the present disclosure;

FIG. 7 is a cross-sectional view of a warpage compensation wafer, taken along cutting line II-II of FIG. 6;

FIG. 8 is a diagram illustrating an example warpage type;

FIG. 9A is a flowchart illustrating a method of manufacturing a warpage compensation wafer according to some embodiments of the present disclosure;

FIG. 9B is a flowchart illustrating a method of installing a reinforcement structure according to some embodiments of the present disclosure;

FIG. 10 is a flowchart illustrating a semiconductor manufacturing method according to some embodiments of the present disclosure;

FIG. 11 is a flowchart illustrating a semiconductor manufacturing method according to some embodiments of the present disclosure;

FIG. 12A is a flowchart illustrating a semiconductor manufacturing method according to some embodiments of the present disclosure;

FIG. 12B is a table illustrating warpage types according to some embodiments of the present disclosure;

FIG. 13 is a flowchart illustrating a method of reusing a warpage compensation wafer according to some embodiments of the present disclosure;

FIG. 14A is a flowchart illustrating a method of manufacturing a warpage compensation wafer according to some embodiments of the present disclosure;

FIG. 14B is a cross-sectional view of a warpage compensation wafer according to some embodiments of the present disclosure;

FIG. 15A is a flowchart illustrating a method of manufacturing a warpage compensation wafer according to some embodiments of the present disclosure; and

FIG. 15B is a cross-sectional view of a warpage compensation wafer according to some embodiments of the present disclosure.

### DETAILED DESCRIPTION

Hereinafter, example embodiments will be described in detail with reference to the accompanying drawings. However, various modifications and changes may be made to the embodiments and the scope of the patent application is not limited or circumscribed by these embodiments. It is to be understood that any modifications, equivalents, or substitutions to the embodiments are included in the scope of the claims.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Unless otherwise defined, all terms used herein including technical or scientific terms have the same meanings as those generally understood consistent with and after an understanding of the present disclosure. Terms, such as those defined in commonly used dictionaries, should be construed to have meanings matching with contextual meanings in the relevant art and the present disclosure, and are not to be construed as an ideal or excessively formal meaning unless otherwise defined herein.

Also, in the following description with reference to the accompanying drawings, identical components are given the same reference numerals regardless of signs in the drawings, and repeated descriptions thereof may be omitted in the interest of brevity. In describing the example embodiments, if it is determined that a detailed description of the relevant known art would unnecessarily obscure the essence of the embodiments, the detailed description may be omitted.

Also, terms such as first, second, A, B, (a), (b), and the like may be used to describe components of some embodiments. These terms are intended only to distinguish one component from another, and the nature, sequence, or order of the components is not limited by the terms. Where a component is described as “connected,” “coupled,” or “bonded” to another component, it is to be understood that the component may be directly connected, coupled, or bonded to the other component, but also that there may be another component intervening therebetween.

Also, components included in one embodiment, and components having common features, may be described using the same designations in other embodiments. Unless otherwise indicated, the description of one embodiment is applicable to the other embodiments, and detailed and repeated descriptions thereof may be omitted in the interest of brevity.

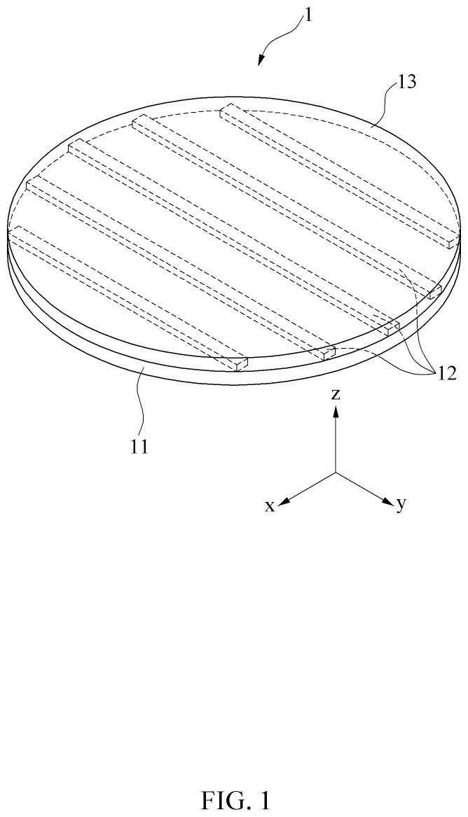

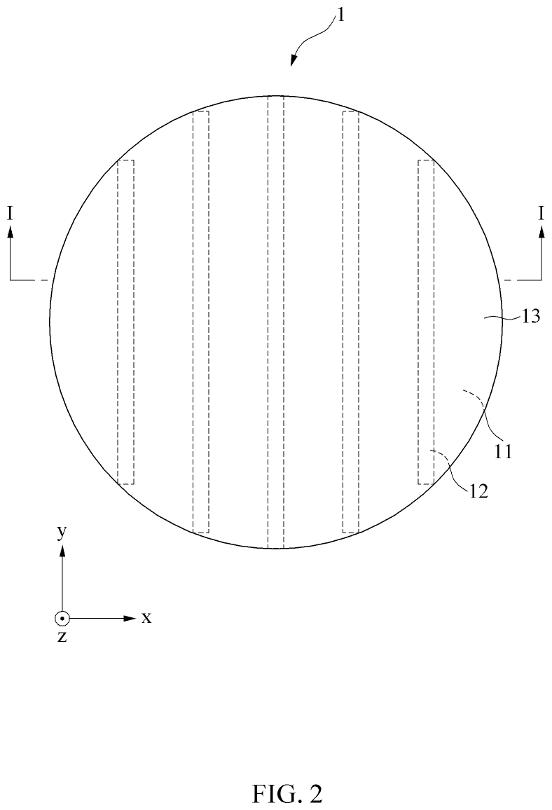

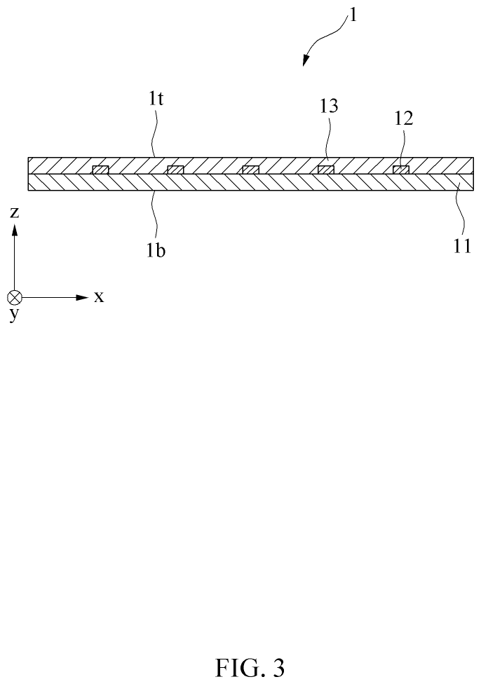

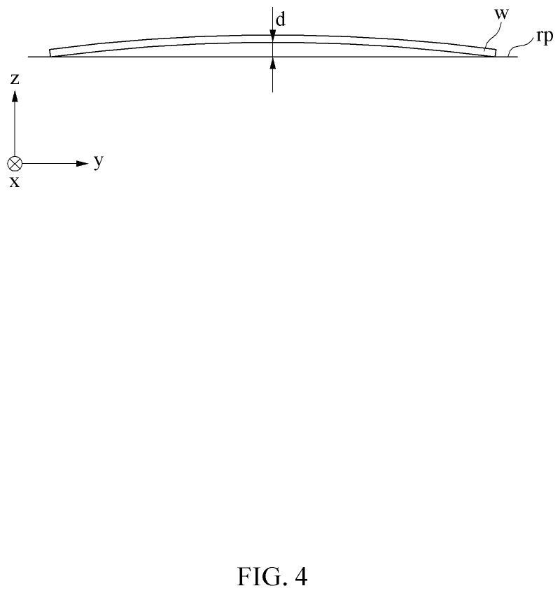

FIG. 1 is a perspective view of a warpage compensation wafer according to some embodiments of the present disclosure, FIG. 2 is a top view of a warpage compensation wafer according to some embodiments of the present disclosure, FIG. 3 is a cross-sectional view of a warpage compensation wafer, taken along cutting line I-I of FIG. 2, and FIG. 4 is a diagram illustrating an example warpage type.

Referring to FIGS. 1 through 4, according to some embodiments of the present disclosure, a warpage compensation wafer 1 may be used as a support plate in semiconductor manufacturing processes. For example, the warpage compensation wafer 1 may be used in a process that may cause warpage, as shown in FIG. 4, to reduce potential warpage that may occur in a resulting product from the process (or simply referred to herein as a “process product”) disposed on a base layer 11 and/the warpage compensation wafer 1.

The warpage compensation wafer 1 may be provided in a shape of a flat plate having a flat or planar top surface 1t and a flat or planar bottom surface 1b. This shape may allow a semiconductor manufacturing process (e.g., a deposition process) to be performed directly on the top surface 1t, and the bottom surface 1b of the warpage compensation wafer 1 to be stably chucked into a chuck apparatus among semiconductor equipment apparatuses. Although the warpage compensation wafer 1 is illustrated as being provided in a circular shape as an example, the shape of the warpage compensation wafer 1 is not necessarily limited thereto. For example, when used in a panel-level package process, the warpage compensation wafer 1 may have a rectangular or square shape. The warpage compensation wafer 1 may include the base layer 11, a reinforcement structure 12, and a temporary layer 13.

The base layer 11 may have the flat bottom surface 1b. On the bottom surface 1b of the base layer 11 or the bottom surface 1b of the warpage compensation wafer 1, the reinforcement structure 12 may not be installed. This shape may facilitate smooth chucking of the warpage compensation wafer 1 in preparation for an event where there is an uneven structure on the bottom surface 1b. The base layer 11 may be formed of various materials that may be used, for example, as a support plate in a semiconductor manufacturing process. The base layer 11 may be formed of, for example, an elemental semiconductor material or a compound semiconductor material. The “elemental semiconductor material” may refer to a material that exhibits semiconductivity as a single element and may include, for example, silicon (Si), germanium (Ge), or selenium (Se). The “compound semiconductor material” may refer to a material including two or more materials and may include, for example, (i) a III-V compound such as gallium-arsenide (GaAs), indium-phosphorus (InP), or gallium-phosphorus (GaP), (ii) a II-VI compound such as cadmium sulfide (CdS) or zinc telluride (ZnTe), (iii) a IV-VI compound such as lead sulfide (PbS), or the like. The base layer 11 may also be formed of, for example, a compound material in which another element different from the elemental or compound semiconductor material described above is compounded. However, it is to be noted that these are provided only as examples, and that the material of the base layer 11 is not necessarily limited to the foregoing, unless the appended claims state to the contrary.

As the reinforcement structure 12, one or more reinforcement structures may be installed on the top surface of the base layer 11. These reinforcement structures 12 may allow at least a portion of the warpage compensation wafer 1 disposed on the top surface of the base layer 11 to have an anisotropic bending stiffness. The “anisotropic bending stiffness” described herein may be construed as a bending stiffness of at least a portion of any member that varies depending on a direction in which it is measured. That is, the reinforcement structures 12 may allow the bending stiffness of the at least a portion of the warpage compensation wafer 1 disposed on the top surface of the base layer 11 to be non-uniform. By this configuration described above, designing the warpage compensation wafer 1 in response to warpage of a certain shape may be possible, reducing the occurrence of warpage in a semiconductor manufacturing process.

For example, in the warpage compensation wafer 1 in which the reinforcement structure 12 is installed, an amount deformed by a bending moment centered on a first axis (e.g., an x-axis) may be smaller than an amount deformed by a bending moment centered on a second axis (e.g., a y-axis) that is different from the first axis (e.g., the x-axis). That is, in the case of the warpage compensation wafer 1, a bending stiffness centered on the first axis (e.g., the x-axis) may be greater than the bending stiffness centered on the second axis (e.g., the y-axis). For example, in a case where a plurality of bars elongated along the second axis (e.g., the y-axis), formed as the reinforcement structure 12, are spaced apart along the first axis (e.g., the x-axis) in parallel to each other, as shown in FIGS. 1 through 3, the bending stiffness of the warpage compensation wafer 1 around the first axis (e.g., the x-axis) may be improved. According to some embodiments, the warpage compensation wafer 1 may be used to reduce the warpage of a crying shape that is bent upward (e.g., upwardly convex) by receiving the bending moment around the first axis (e.g., the x-axis) as shown in FIG. 4.

FIG. 4 shows how a wafer (w) having a flat shape with respect to a reference plane (rp) before an external force is applied is warped upward by receiving a bending moment around a first axis (e.g., an x-axis). FIG. 4 shows an example of a crying-shaped warpage, from which it may be verified that a portion corresponding to a straight line passing through the center of the wafer w before the external force is applied has an upward deviation d with respect to the reference plane rp. When the crying-shaped warpage shown in FIG. 4 is predicted, a warpage compensation wafer (e.g., the warpage compensation wafer 1) having a high bending stiffness in response to the bending moment around the first axis (e.g., the x-axis) may be used as a support plate in a semiconductor manufacturing process, as described above.

However, the shape and configuration of the reinforcement structure 12 is not necessarily limited to the one shown in FIGS. 1 through 3, and the shape of the reinforcement structure 12 may vary according to a warpage type. For example, the reinforcement structure 12 may be provided as a total of five reinforcement structures. However, in the case of severe warpage, the number of reinforcement structures 12 may be increased to six or more to increase the stiffness. For example, the reinforcement structure 12 may be provided in a form that crosses straightly the warpage compensation wafer 1 to have a length that connects both points of an edge of the warpage compensation wafer 1. On the other hand, in a case where the warpage occurs only in a center portion but not in an edge portion, the length of the reinforcement structure 12 may be reduced such that the reinforcement structure 12 is not to be positioned in the edge portion of the warpage compensation wafer 1. For example, the width of the reinforcement structure 12 may be 1/20 to 1/10 of the maximum width of the warpage compensation wafer 1. On the other hand, in the case of severe warpage, the width of the reinforcement structure 12 may be increased to increase the stiffness. For example, the height of the reinforcement structure 12 may be ⅖ to ⅗ of the thickness of the temporary layer 13. On the other hand, in the case of slight warpage, the height of the reinforcement structure 12 may be reduced to save the material. For example, the reinforcement structure 12 may be disposed in parallel to the first axis (e.g., the x-axis). On the other hand, in a case where warpage occurs due to a combination of the bending moment around the first axis (e.g., the x-axis) and the bending moment around the second axis (e.g., the y-axis) orthogonal to the first axis (e.g., the x-axis), a plurality of bars parallel to the first axis (e.g., the x-axis) and a plurality of bars parallel to the second axis (e.g., the y-axis) may be used as the reinforcement structure 12. For example, the reinforcement structures 12 may be disposed to form a grid-shaped arrangement. It is to be noted that the number, length, width, height, and/or arrangement of the reinforcement structures 12 may vary depending on a warpage type, as described herein.

The reinforcement structure 12 may be formed of a material (e.g., metal) having a stiffness that is greater than that of a material (e.g., silicone) of the base layer 11. For example, the stiffness of the material of the reinforcement structure 12 may be more than twice the stiffness of the material of the base layer 11. The reinforcement structure 12 may be disposed on a portion of the top surface of the base layer 11. For another example, the reinforcement structure 12 may be disposed to cover the entirety of the top surface of the base layer 11. However, this structure may increase the cost required for manufacturing the warpage compensation wafer 1, in a case where the material of the reinforcement structure 12 (e.g., metal) is relatively more expensive than the material of the base layer 11 (e.g., silicon). That is, partially forming the reinforcement structure 12 only in a portion of which the bending stiffness is required to be reinforced may reduce an overall semiconductor manufacturing cost.

The reinforcement structure 12 of the configuration or structure described above may allow at least a portion of the temporary layer 13 to be directly bonded to the base layer 11. In this case, an adhesive force of the temporary layer 13 to the base layer 11 may be greater than that of the reinforcement structure 12 to the base layer 11. By this configuration, direct adhesion (or bonding) of the base layer 11 and the temporary layer 13 may reduce the likelihood of delamination of the temporary layer 13 and improve the stability of the manufacturing processes.

For example, the reinforcement structure 12 may be installed to have a shape that protrudes or extends from the top surface of the base layer 11. In this case, a portion in an upper space of the base layer 11 in which the reinforcement structure 12 is not installed may be referred to as a “recess,” and a protruding portion of the temporary layer 13 may be inserted into the recess to engage with the reinforcement structure 12. Such an engaging structure between the reinforcement structure 12 and the temporary layer 13 may improve a bonding force of the reinforcement structure 12 and the temporary layer 13.

The temporary layer 13 is a portion that is temporarily present to support a resulting process product in a semiconductor manufacturing process, and at least a portion of the temporary layer 13 may be removed from the process product after the semiconductor manufacturing process is completed. As the temporary layer 13 is removed, the warpage compensation wafer 1 may be separated from the process product, and the base layer 11 and the reinforcement structure 12 of the warpage compensation wafer 1 may be reused. In some embodiments, the temporary layer 13 may be removed entirely from the process product. In some other embodiments, at least a portion of the temporary layer 13 may remain on a bottom surface of the process product to be planarized, forming a bottom layer of the process product.

The temporary layer 13 may be stacked on the base layer 11 and on the reinforcement structure 12, which may allow the reinforcement structure 12 to have a shape that is embedded in the temporary layer 13. The temporary layer 13, thereby covering the base layer 11 and the reinforcement structure 12, may have the flat top surface 1t. The top surface 1t of the warpage compensation wafer 1 may be the top surface 1t of the temporary layer 13. For example, a semiconductor manufacturing process (e.g., a deposition process) may be performed directly on the flat top surface 1t of the temporary layer 13.

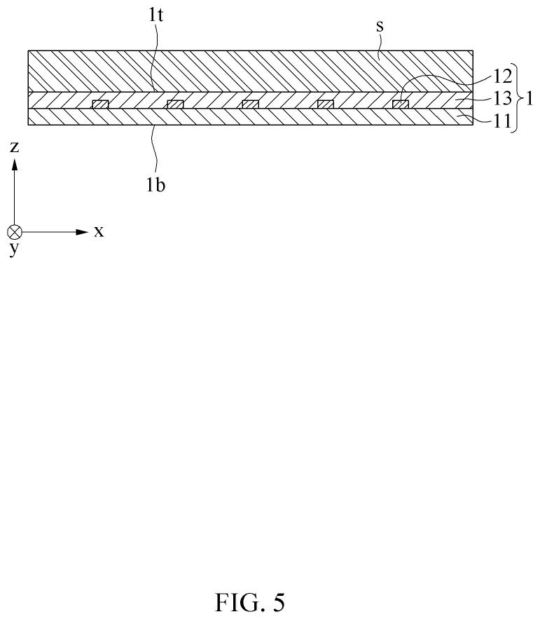

FIG. 5 is a cross-sectional view of a semi-finished semiconductor product formed on a top surface of a warpage compensation wafer according to some embodiments of the present disclosure.

Referring to FIG. 5, a semi-finished semiconductor product(s) may be formed as a semiconductor manufacturing process is performed directly on the top surface 1t of the warpage compensation wafer 1 according to some embodiments of the present disclosure. The semi-finished semiconductor product s may also be referred to herein as a “resulting process product” (or simply a process product).

The reinforcement structure 12 may be used to reduce warpage of the base layer 11 and/or the semi-finished semiconductor product s that may occur in a semiconductor manufacturing process and manufacture the semi-finished semiconductor product s of a flat shape as shown.

The temporary layer 13 may have a property that allows a material of the semi-finished semiconductor product s to be well deposited thereon such that the semiconductor manufacturing process is directly performed. The temporary layer 13 may be formed of various materials that may be used as, for example, a support plate for the semiconductor manufacturing process. For example, the temporary layer 13 may be formed of an elemental semiconductor material or a compound semiconductor material or may be formed of a compound material (e.g., silicon nitride) in which another element is compounded. It is to be noted that the material of the temporary layer 13 is not necessarily limited to the foregoing, unless the appended claims state to the contrary.

For example, the temporary layer 13 may be formed of a material different from a material of the semi-fished semiconductor product s such that the temporary layer 13 is well separated from the semi-fished semiconductor product s.

For example, in the process of separating the temporary layer 13 from the semi-finished semiconductor product s, to reduce the impact on the base layer 11 to be reused, the temporary layer 13 may be formed of a material different from a material of the base layer 11. The process of separating the temporary layer 13 from the semi-finished semiconductor product s will be described in detail below.

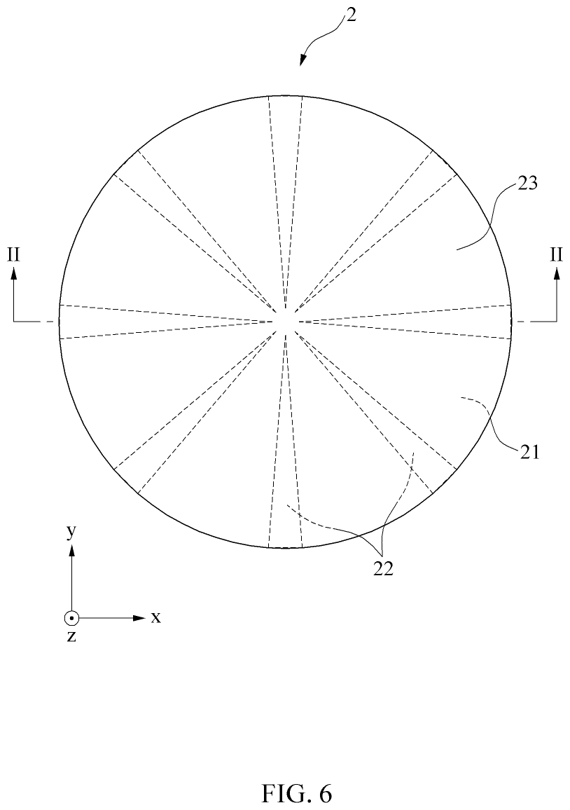

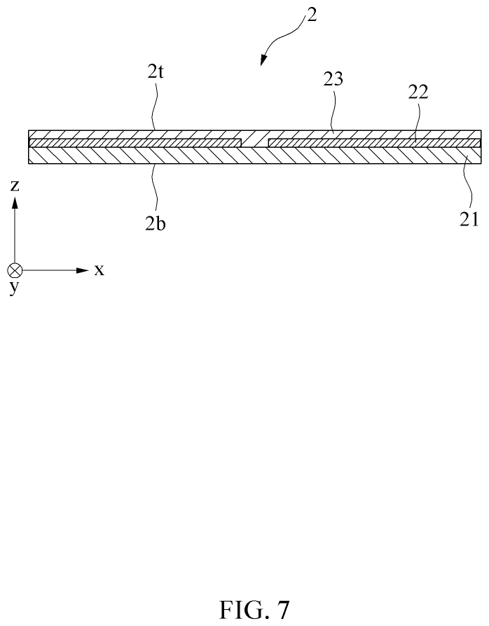

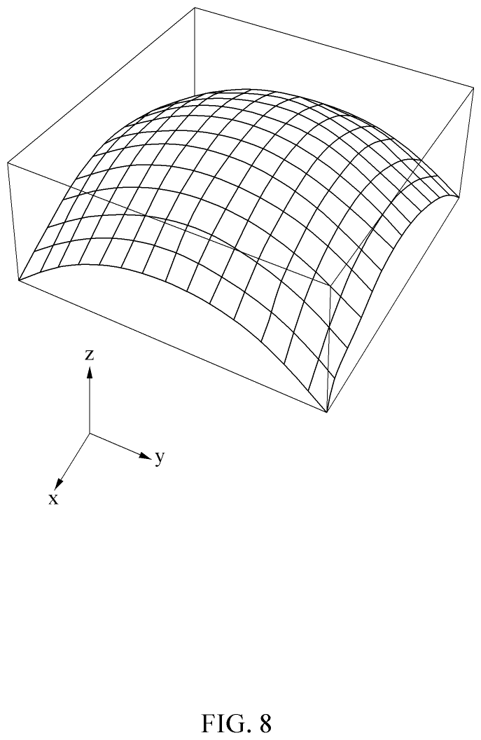

FIG. 6 is a top view of a warpage compensation wafer according to some embodiments of the present disclosure, FIG. 7 is a cross-sectional view of a warpage compensation wafer, taken along cutting line II-II of FIG. 6, and FIG. 8 is a diagram illustrating an example warpage type.

Referring to FIGS. 6 through 8, according to some embodiments of the present disclosure, a warpage compensation wafer 2 may include a base layer 21, a reinforcement structure 22, and a temporary layer 23.

For example, in the warpage compensation wafer 2 in which the reinforcement structure 22 is installed, an amount deformed by a bending moment centered on a first straight line passing through a ½ point between the center and the edge of the base layer 21 may be less than an amount deformed by a bending moment centered on a second straight line passing through the center of the base layer 21. That is, in the case of the warpage compensation wafer 2, a bending stiffness based on the first straight line described above may be greater than a bending stiffness based on the second straight line described above. For example, in a case where a plurality of bars, as the reinforcement structure 22, are radially spaced apart from each other with respect to the center of the base layer 21, as shown in FIGS. 6 and 7, the bending stiffness of the warpage compensation wafer 2 around the first straight line may be improved.

FIG. 8 shows an example of warpage of an arch shape with a center portion protruding upwardly relative to an edge portion. In a case where such an arch-shaped warpage shown in FIG. 8 is predicted, a warpage compensation wafer (e.g., the warpage compensation wafer 2) having a high bending stiffness in response to the bending moment around the first straight line described above may be used as a support plate in a semiconductor manufacturing process.

For example, the width of the reinforcement structure 22 may increase as it develops farther (radially) from the center of the warpage compensation wafer 2. This shape may improve the bending stiffness of the edge portion compared to the center portion.

The warpage compensation wafers 1 and 2 described with reference to FIGS. 1 through 8 may be respectively referred to as a “first warpage compensation wafer 1” and a “second warpage compensation wafer 2” to distinguish them from each other. The reinforcement structure 12 of the first warpage compensation wafer 1 and the reinforcement structure 22 of the second warpage compensation wafer 2 may differ in shape. Their shapes may be designed or selected according to a warpage type. Although a simple shape of warpage has been described herein to assist in understanding, there are various other shapes of warpage, such as, for example, a smile shape, a bow shape, and a saddle shape. It is to be understood that the idea of using a warpage compensation wafer designed for each warpage shape is also included in the scope of the appended claims.

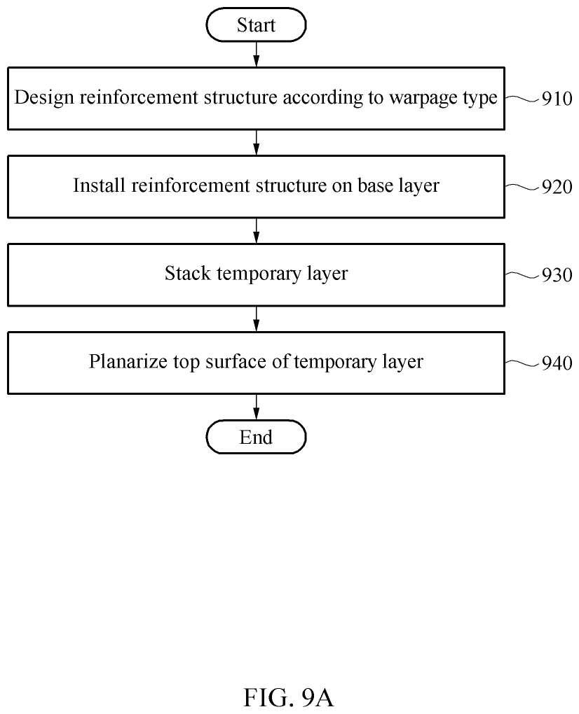

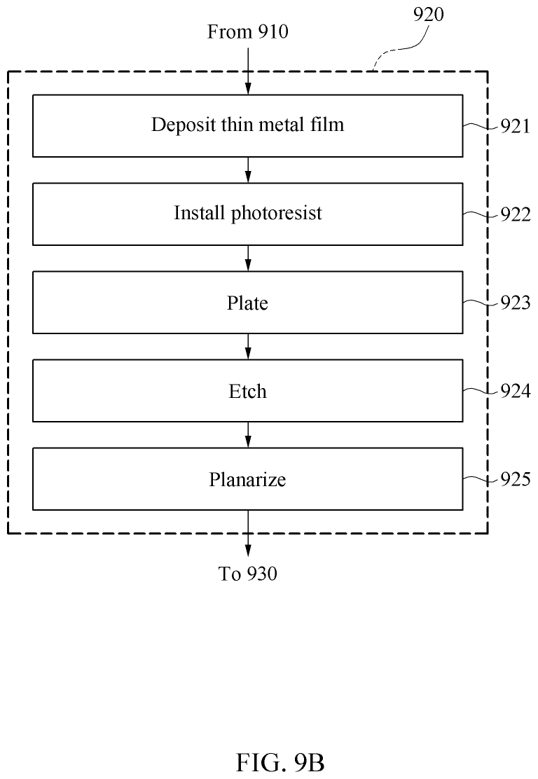

FIG. 9A is a flowchart illustrating a method of manufacturing a warpage compensation wafer according to some embodiments of the present disclosure, and FIG. 9B is a flowchart illustrating a method of installing a reinforcement structure according to some embodiments of the present disclosure.

Referring to FIG. 9A, according to some embodiments of the present disclosure, a method of manufacturing a warpage compensation wafer may include step 910 of designing a reinforcement structure according to a warpage type; step 920 of installing the reinforcement structure on a top surface of a base layer; step 930 of stacking a temporary layer covering the top of the base layer and the top of the reinforcement structure; and step 940 of planarizing a top surface of the temporary layer.

In some embodiments, step 910 may be performed based on various experimental or simulation results. For example, a warpage type may be determined based on a measurement result obtained by measurements using a non-contact optical sensor device. The non-contact optical sensor device may measure a deviation that each point of the base layer deviates from a reference plane after the actual performance of a certain process. For another example, a warpage type may be determined based on a simulation result obtained by simulations based on physical properties of a material of the base layer according to temperature and on temperature information of a process to be performed. This simulation result may include information about the deviation of each point of the base layer from the reference plane after the process is performed. According to a warpage type determined as described above, the reinforcement structure may be designed to compensate for the warpage type. Once a warpage type is determined, an axial direction of a bending moment that may cause the determined warpage type and/or a magnitude of the bending moment may be calculated through experiments or simulations. For example, the magnitude of the bending moment may be calculated using a deviation (d) with respect to a reference plane (rp), as shown in FIG. 4. For example, the reinforcement structure(s) may be designed to form an elongated arrangement in a direction orthogonal to the axial direction of the bending moment. For example, at least one of the number, length, width, or height of the reinforcement structure(s) may be designed to increase as the magnitude of the bending moment increases.

For example, for a warpage type having a crying shape about a first axis (e.g., an x-axis) as shown in FIG. 4, the reinforcement structure(s) may be designed to form an elongated arrangement along a second-axis (e.g., a y-axis) direction orthogonal to the first axis (e.g., the x-axis). For example, at least one of the number, length, width, or height of the reinforcement structure(s) may be increased in proportion to the deviation d measured or calculated as described with reference to FIG. 4.

Step 920 may be a process of installing the reinforcement structure designed in step 910 on the base layer, and the installation may be performed in various ways. For example, the reinforcement structure may be formed directly on the base layer using semiconductor equipment used in a semiconductor manufacturing process (e.g., a metal film deposition process, a photolithography process, and/or a metal plating process). For example, referring to FIG. 9B, in step 921, a physical vapor deposition (PVD) apparatus may deposit a thin metal film on the top surface of the base layer. In step 922, a photosensitive material may be coated on the thin metal film. In this case, on the photosensitive material, an exposure process may be performed using a mask according to the shape of the designed reinforcement structure, and a development process may then be performed to form a photoresist according to the shape of the designed reinforcement structure. In step 923, a plating process may be performed to form a metal layer according to the shape of the designed reinforcement structure. In step 924, an etching process may be performed to remove the photoresist. In step 925, a chemical mechanical polishing (CMP) process may be performed to planarize the top surface of the formed reinforcement structure.

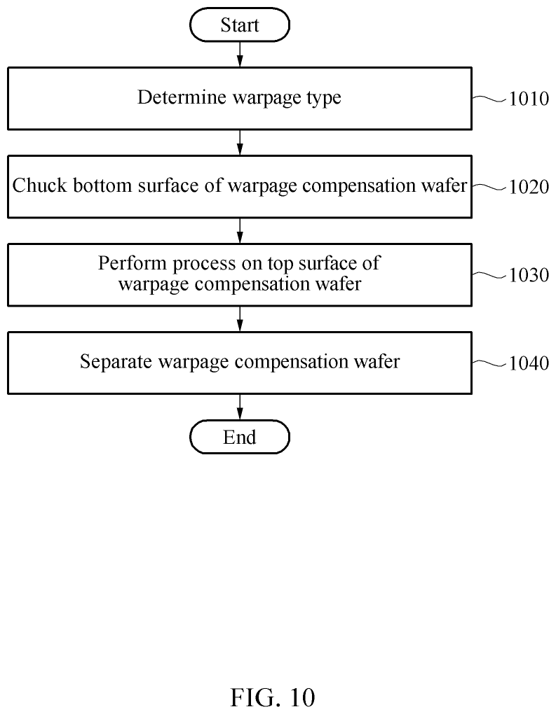

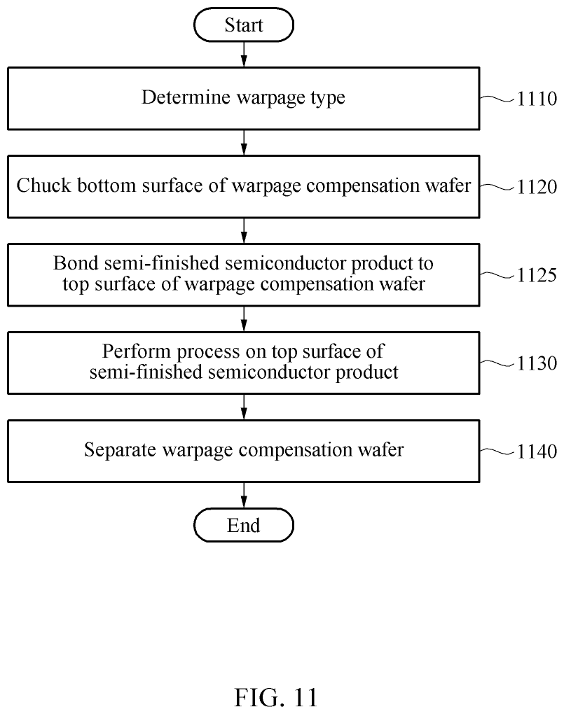

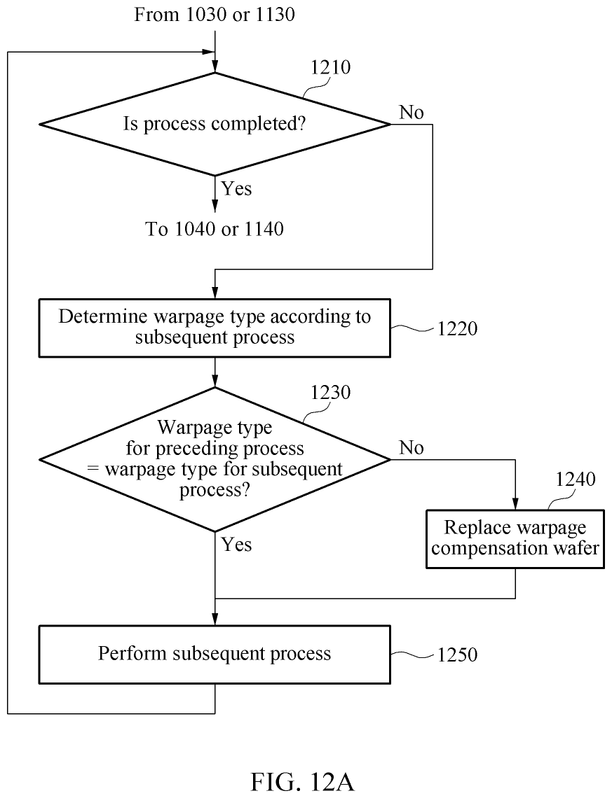

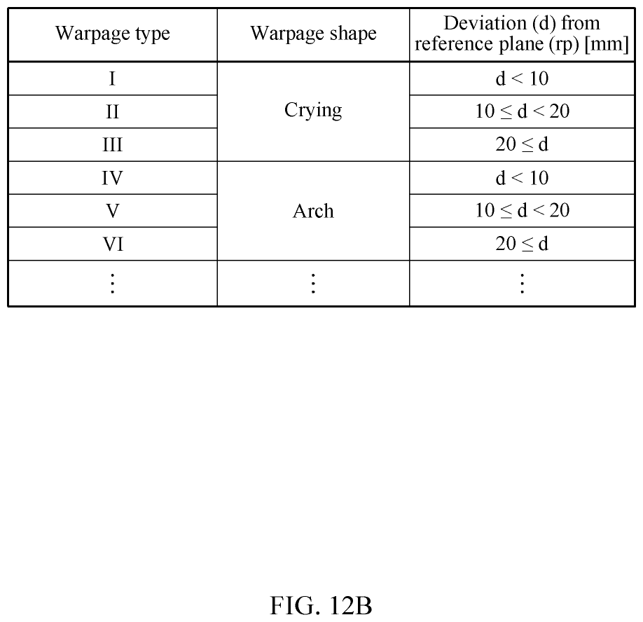

Step 920 may be performed, for example, with the base layer secured to equipment used to perform a subsequent semiconductor manufacturing process (e.g., step 1030 of FIG. 10, step 1130 of FIG. 11, or step 1250 of FIG. 12A). In this way, it is not necessary to introduce a separate apparatus for installing the reinforcement structure, saving manufacturing costs and time. As opposed to this, however, in step 920, the reinforcement structure may be formed separately from the base layer and may then be bonded to the base layer.

In step 930, the temporary layer may be formed of various materials that may be used as a support plate in a semiconductor manufacturing process. This may allow the semiconductor manufacturing process (e.g., a deposition process) to be performed directly on the top surface of the temporary layer. Step 930 may be performed using various deposition methods including, for example, chemical vapor deposition (CVD) or PVD. However, step 930 is not necessarily limited to the deposition method, and various other semiconductor manufacturing processes may be used in step 930.

For example, the temporary layer may be formed of a material having the same and/or similar chemical and physical properties as or to the material of the base layer. The temporary layer may be formed of the same material as the material of the base layer or may be formed of a material including the same elements as those in the material of the base layer. For example, in a case where the material of the base layer is silicon (Si), the temporary layer may be formed of silicon or silicon nitride.

For example, the temporary layer may be formed of a material having a desirable bonding force to be bonded to a material of a semi-finished semiconductor product to be formed on the top surface of the temporary layer. The temporary layer may be formed of a material having the same and/or similar chemical and/or physical properties as or to the material of the semi-finished semiconductor product described above. The temporary layer may be formed of the same material as the material of the semi-finished semiconductor product or may be formed of a material including the same elements as those in the material of the semi-finished semiconductor product. For example, in a case where the material of the semi-finished semiconductor product is silicon, the temporary layer may be formed of silicon or silicon nitride.

In step 940, the top surface of the temporary layer may be planarized or flattened, and the top surface of the warpage compensation wafer may thereby have a flat shape. This shape may allow a semiconductor manufacturing process to be performed directly on the top surface of the warpage compensation wafer. Step 940 may be performed in various ways including, for example, a CMP process or an etchback process.

FIG. 10 is a flowchart illustrating a semiconductor manufacturing method according to some embodiments of the present disclosure.

Referring to FIG. 10, according to some embodiments of the present disclosure, a semiconductor manufacturing method may include step 1010 of determining a warpage type; step 1020 of chucking a bottom surface of a warpage compensation wafer; step 1030 of performing a process on a top surface of the warpage compensation wafer; and step 1040 of separating the warpage compensation wafer.

In some embodiments, step 1010 may be performed based on various experimental or simulation results. For example, a warpage type may be determined based on a measurement result obtained by measurements using a non-contact optical sensor device. The non-contact optical sensor device may measure a deviation that each point of a base layer deviates from a reference plane after the process in step 1030 is performed using the base layer instead of the warpage compensation wafer. For another example, a warpage type may be determined based on a simulation result obtained by simulations based on physical properties of a material of the base layer according to temperature and on temperature information of the process to be performed. In this example, when the deviation from the reference plane increases from both sides of the base layer toward a first axis passing through the center of the base layer, the warpage type may be determined to be a crying shape (e.g., upwardly convex). Also, when the deviation from the reference plane decreases from both sides of the base layer toward the first axis passing through the center of the base layer, the warpage type may be determined to be a smile shape (e.g., downwardly convex). Although a warpage type is described herein as including information about a shape, it is to be noted that the warpage type may include information about a deviation with respect to a reference plane in addition to the shape. For example, even for warpages of the same shape, a warpage type may differ depending on a magnitude of a deviation from a reference plane, which is described below with reference to FIG. 12B. Once a warpage type is determined in step 1010 as described above, a subsequent step may be performed by manufacturing and/or loading a warpage compensation wafer corresponding to the determined warpage type. To this end, each warpage compensation wafer may be categorized according to a warpage type and stored in a designated location.

In step 1020, the bottom surface of the warpage compensation wafer may be chucked into a chuck apparatus of semiconductor manufacturing equipment. The semiconductor manufacturing equipment described herein may be pieces of equipment (or apparatuses) for performing step 1030, which may vary depending on the process to be performed in step 1030. For example, in a case where a deposition process is to be performed in step 1030, the bottom surface of the warpage compensation wafer may be chucked onto a chuck apparatus of equipment performing CVD or PVD.

In step 1030, a semiconductor manufacturing process may be performed directly on the top surface of the temporary layer. The semiconductor manufacturing process in step 1030 may include, for example, a process of forming a semi-finished semiconductor product by deposition on the top surface of the temporary layer. Step 1030 may be performed using various deposition methods including, for example, CVD or PVD. However, it is to be noted that step 1030 is not necessarily limited to the deposition method, and various other semiconductor manufacturing processes may be used in step 1030.

In step 1040, the warpage compensation wafer may be separated from the semi-finished semiconductor product formed in step 1030. For example, step 1040 may be performed by an etching method. Step 1040 may be performed using various etching methods including, for example, wet etch or dry etch.

For example, an etch rate of an etchant used in step 1040 for the temporary layer may be higher than an etch rate for the semi-finished semiconductor product. It is to be noted that a material of the temporary layer does not need to be different from that of the semi-finished semiconductor product. For example, even if the temporary layer and the semi-finished semiconductor product are formed of the same material, the wet etch method may immerse only the temporary layer into the etchant to separate the warpage compensation wafer from the semi-finished semiconductor product.

For example, the etch rate of the etchant used in step 1040 for the temporary layer may be higher than an etch rate for the base layer. This may reduce the extent to which the base layer is etched in step 1040, thereby increasing the number of times of reusing the separated warpage compensation wafer. For example, in a case where, under the assumption that the temporary layer and the base layer have the same thickness, an etchant having an etch rate for the temporary layer that is at least three times higher than an etch rate for the base layer is used in step 1040, the warpage compensation wafer may be reused three or more times. For example, the base layer may be formed of silicon (Si) and the temporary layer may be formed of silicon nitride. In this case, phosphoric acid (H₃PO₄) or hydrofluoric acid (HF) may be used as the etchant to allow the temporary layer to be etched faster than the base layer.

In addition, an etch rate for each material may vary according to atmosphere and etchant settings. The atmosphere settings may be construed as a concept including setting the temperature and pressure of an environment in which step 1040 is performed. The atmosphere settings may be set to be the same as or similar to an atmosphere of a preceding process performed immediately before step 1040. For example, the temperature and pressure for the preceding process may be set to a range of −20% to +20% of the temperature and pressure for step 1040. Under this condition, the warpage that may occur in a resulting process product due to a sudden atmosphere change while the warpage compensation wafer is being separated in step 1040 may be reduced.

It is also to be noted that the etch rate of the etchant used in step 1040 for the temporary layer is not necessarily higher than the etch rate for the base layer. For example, in a case where the thickness of the base layer is greater than the thickness of the temporary layer, even under the condition that the two etch rates are the same, the temporary layer may be etched before the base layer, and the base layer may thus be reused.

Although FIG. 10 illustrates the semiconductor manufacturing method that begins with forming a semi-finished semiconductor product directly on a warpage compensation wafer, the warpage compensation wafer may also be used to perform an additional semiconductor manufacturing process on the prepared semi-finished semiconductor product. This will be described below with reference to FIG. 11. It is to be noted that the steps described with reference to FIGS. 10 and 11 may be performed sequentially.

FIG. 11 is a flowchart illustrating a semiconductor manufacturing method according to some embodiments of the present disclosure.

Referring to FIG. 11, according to some embodiments of the present disclosure, a semiconductor manufacturing method may include step 1110 of determining a warpage type; step 1120 of chucking a bottom surface of a warpage compensation wafer; step 1125 of bonding a semi-finished semiconductor product to a top surface of the warpage compensation wafer; step 1130 of performing a process on a top surface of the semi-finished semiconductor product, and step 1040 of separating the warpage compensation wafer.

It is to be noted that the order of the steps described throughout the specification, including the description provided with reference to FIG. 11, is not limited to the illustrated order, and at least some the steps may be performed in reverse or simultaneously, unless otherwise stated. Further, some steps may be omitted. For example, step 1120 may be performed after step 1125.

Step 1125 may be performed using, for example, a physical bonding method or an electrical bonding method. The physical bonding method may be a method using an adhesive, which is performed by applying an adhesive onto at least one of both sides to be bonded. The electrical bonding method may be a method using electrostatic properties, which is performed by injecting adhesive ions into at least one of both sides to be bonded.

In step 1130, a semiconductor manufacturing process may be performed directly on the top surface of the semi-finished semiconductor product. The semiconductor manufacturing process in step 1130 may be, for example, at least one of a molding process, a diffusion process, a thin film deposition process, a photolithography process, a sputtering process, an electroplating process, a rewiring process, an etching process, and a cleaning process. The semiconductor manufacturing process in step 1130 may also include, for example, a conventional package process, a wafer-level package process, and/or a panel-level package process. It is to be noted that these processes are provided only as examples, and that any process in which warpage may occur may be included as the semiconductor manufacturing process described above.

FIG. 12A is a flowchart illustrating a semiconductor manufacturing method according to some embodiments of the present disclosure, and FIG. 12B is a table illustrating warpage types according to some embodiments of the present disclosure.

Referring to FIGS. 10, 11, 12A, and 12B, a plurality of semiconductor manufacturing processes may be performed in succession and, for each of the processes, a suitable warpage compensation wafer may be selected or used from among a plurality of warpage compensation wafers. For example, the plurality of warpage compensation wafers may include (i) a first warpage compensation wafer that was used in a preceding semiconductor process as of a current time among the plurality of semiconductor manufacturing processes, and (ii) a second warpage compensation wafer that is different from the first warpage compensation wafer. The first warpage compensation wafer and the second warpage compensation wafer may be designed for different warpage types, respectively, and a first reinforcement structure of the first warpage compensation wafer and a second reinforcement structure of the second warpage compensation wafer may differ in shape.

According to some embodiments of the present disclosure, a semiconductor manufacturing method may include step 1210 of determining whether an entire semiconductor manufacturing process has been completed; step 1220 of determining a warpage type according to a subsequent semiconductor manufacturing process; step 1230 of determining whether a warpage type according to a preceding semiconductor process (or a “preceding process” or “first semiconductor manufacturing process”) and a warpage type according to a subsequent semiconductor process (or a “subsequent process” or “second semiconductor manufacturing process”) are the same; step 1240 of replacing the warpage compensation wafer; and step 1250 of performing the subsequent process. For example, steps 1210 through 1250 may be performed between steps 1030 and 1040 of FIG. 10, between steps 1130 and 1140 of FIG. 11, or between step 1030 of FIG. 10 and step 1140 of FIG. 11.

When it is determined in step 1210 that the entire semiconductor manufacturing process has been completed, step 1040 or step 1140 may be performed to separate the warpage compensation wafer from a resulting process product and terminate the process.

When it is determined in step 1210 that the entire semiconductor manufacturing process has not been completed yet, step 1220 may be performed to determine a warpage type for the subsequent process. In some embodiments, step 1220 may be performed based on various experimental or simulation results.

In step 1230, whether the warpage type according to the preceding process (or the first semiconductor manufacturing process) and the warpage type according to the subsequent process (or the second semiconductor manufacturing process) are the same may be determined. When it is determined in step 1230 that the warpage type for the preceding process and the warpage type for the subsequent process are different from each other, step 1240 may be performed to replace the warpage compensation wafer with one suitable for the warpage type for the subsequent process.

That is, a first warpage compensation wafer used in the preceding process may be separated from the semi-finished semiconductor product, and a second warpage compensation wafer to be used in the subsequent process may be bonded to the semi-finished semiconductor product. In this state, the subsequent process may be performed in step 1250. In this way, the warpage may be reduced desirably for each process.

When it is determined in step 1230 that the warpage type for the preceding process and the warpage type for the subsequent process are the same, there is no need to change the warpage compensation wafer, and thus the first warpage compensation wafer used in the preceding process may be used without a change. Therefore, with the first warpage compensation wafer maintained, the subsequent process may be performed in step 1250. That is, in response to the two warpage types being the same, the subsequent process (or the second semiconductor manufacturing process) may be performed directly on the top surface of the semi-finished semiconductor product in step 1250 without replacing the first warpage compensation wafer with the second warpage compensation wafer. In this way, the time required for the manufacturing processes may be reduced.

After step 1250 is performed, the method described above may return to step 1210 to be repeated until the entire semiconductor manufacturing process is completed.

Referring to FIG. 12B, a warpage type may be determined based on, for example, a shape of warpage and a magnitude of a deviation (d) from a reference plane (refer to FIG. 4).

The warpage shape may include, for example, a crying shape and an arch shape. For example, the crying shape may be defined as a shape in which he deviation from the reference plane increases from both sides of the base layer toward a first axis passing through the center of the base layer. For example, the arch shape may be defined as a shape in which the deviation from the reference plane increases from an edge of the base layer toward the center of the base layer. In addition to the shapes described above, warpage may be of various shapes including, for example, a smile shape, a bow shape, and a saddle shape.

The magnitude of the deviation from the reference plane may be, for example, an average value, a minimum value, or a maximum value of deviations at points where the warpage occurs. Even with the same warpage shape, warpage types may be subcategorized depending on the magnitude of the deviation from the reference plane. Based on such categorization, in the case of a great deviation from the reference plane, using a warpage compensation wafer with a higher bending stiffness in a certain direction may desirably reduce warpage. Conversely, in the case of a small deviation from the reference plane, using a warpage compensation wafer with a relatively low bending stiffness and price may increase the lifetime of a warpage compensation wafer compared with a relatively high bending stiffness and price.

On the other hand, for example, warpage types may be categorized by a deviation range from the reference plane. That is, in a case where the deviation from the reference plane is within a certain range, the same warpage compensation wafer may be used to perform a semiconductor manufacturing process. In this way, the number of times of replacing the warpage compensation wafer may be reduced, and a subsequent process may be performed using the same warpage compensation wafer, which may reduce the time required for the manufacturing process.

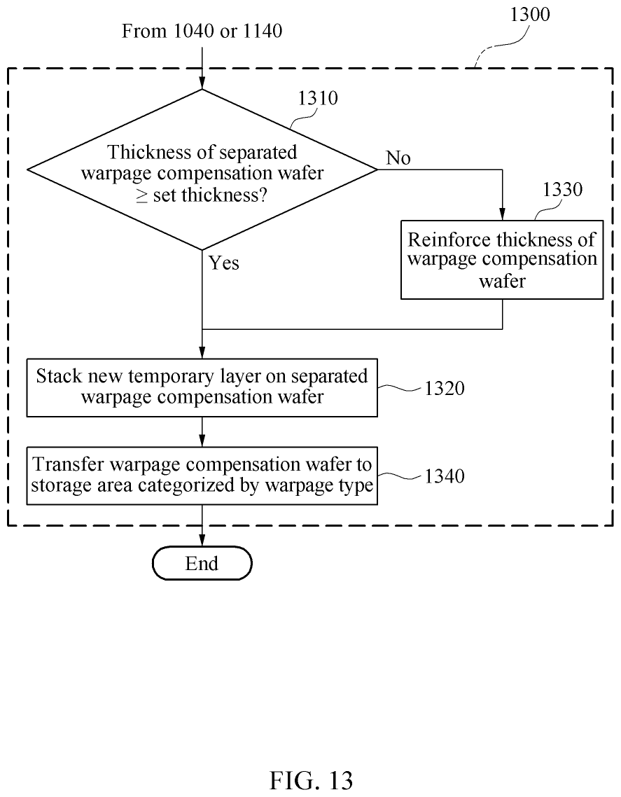

FIG. 13 is a flowchart illustrating a method of reusing a warpage compensation wafer according to some embodiments of the present disclosure.

Referring to FIGS. 10, 11, and 13, according to some embodiments of the present disclosure, a method of reusing a warpage compensation wafer 1300 may be performed as part of the semiconductor manufacturing method described above after step 1040 of FIG. 10 or step 1140 of FIG. 11.

The method 1300 may include step 1310 of determining whether a measured thickness of a separated warpage compensation wafer or a first base layer is greater than or equal to a set thickness; step 1320 of stacking a new temporary layer on the separated warpage compensation wafer; step 1330 of increasing the thickness of the warpage compensation wafer, and step 1340 of transferring the warpage compensation wafer to a storage area categorized by a warpage type.

In step 1310, the thickness of the warpage compensation wafer or the base layer may be measured. Depending on how much the thickness of the base layer has been reduced, it may be determined whether the base layer is to be reused as is. Alternatively, the thickness of the base layer may be indirectly determined by measuring the thickness of the entire warpage compensation wafer.

In response to the thickness measured in step 1310 being greater than or equal to the set thickness, the base layer may be reused as is. In this case, step 1320 may be performed to stack the new temporary layer on the base layer and on the reinforcement structure.

In some embodiments, in step 1320, the temporary layer may be stacked on the separated warpage compensation wafer by deposition. In step 1320, the same material as the temporary layer may be deposited on the separated warpage compensation wafer using, for example, CVD, PVD, or atomic layer deposition (ALD). In step 1320, the deposition process may be performed until the thickness of the temporary layer becomes the same as the thickness of a temporary layer of an unused warpage compensation wafer. For example, the deposition process may be performed until the thickness at all points of the temporary layer becomes greater than or equal to the thickness of the temporary layer of the unused warpage compensation wafer, and then planarization may be performed through a CMP process. The CMP process may be performed until the thickness at all points of the temporary layer becomes the same as the thickness of the temporary layer of the unused warpage compensation wafer. After step 1320, step 1340 may be performed to categorize and store warpage compensation wafers by warpage type.

In response to the thickness measured in step 1310 being less than the set thickness, the base layer may be considered to have been etched too much to be reused. Therefore, in step 1330, the thickness of the base layer may be increased by deposition and the like. For example, in step 1330, the same material as the base layer may be deposited on the base layer using a CVD, PVD, or ALD method. In step 1330, the deposition process may be performed until the thickness of the base layer becomes the same as the thickness of a base layer of an unused warpage compensation wafer. For example, the deposition process may be performed until the thickness at all points of the base layer becomes greater than or equal to the thickness of the base layer of the unused warpage compensation wafer, and then planarization may be performed through a CMP process. The CMP process may be performed until the thickness at all points of the base layer becomes the same as the thickness of the base layer of the unused warpage compensation wafer.

Alternatively, in response to the thickness measured in step 1310 being less than the set thickness, a notification of this may be provided to an operator such that the operator may decide whether to reuse it or not.

It is to be fully understood by a person having ordinary skill in the art that step 1320, step 1330, and step 1340 may be performed without performing step 1310. For example, step 1320 may be performed each time a warpage compensation wafer is separated from a semi-finished semiconductor product. For example, step 1330 may be performed when the number of times the warpage compensation wafer is separated from the semi-finished semiconductor product exceeds a set number of times, based on a known etch rate of the base layer.

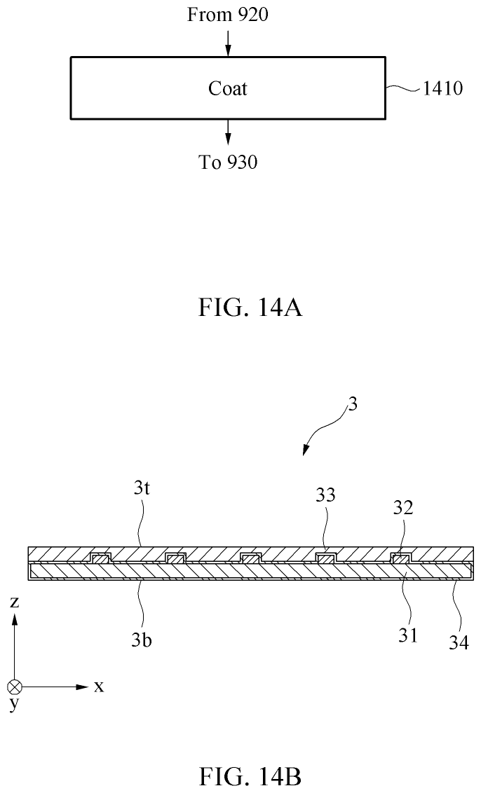

FIG. 14A is a flowchart illustrating a method of manufacturing a warpage compensation wafer according to some embodiments of the present disclosure, and FIG. 14B is a cross-sectional view of a warpage compensation wafer according to some embodiments of the present disclosure.

Referring to FIGS. 9A, 14A, and 14B, according to some embodiments of the present disclosure, a method of manufacturing a warpage compensation wafer may further include step 1410 of forming a coating layer 34 that covers at least a portion of a base layer 31 and has a lower etch rate than that of the base layer 31. Using the coating layer 34 may reduce the extent to which the base layer 31 is etched during the separation of a warpage compensation wafer 3. Therefore, the number of times of reusing the warpage compensation wafer 3 may be increased.

The warpage compensation wafer 3 formed through step 1410 may include the base layer 31, a reinforcement structure 32, a temporary layer 33, and the coating layer 34. In this case, a top surface 3t of the warpage compensation wafer 3 may be the same as the top surface 3t of the temporary layer 33, and a bottom surface 3b of the warpage compensation wafer 3 may be the same as the bottom surface 3b of the coating layer 34. In this case, forming the bottom surface 3b of the coating layer 34 to be flat or planar may enable stable chucking onto a chuck apparatus among semiconductor manufacturing apparatuses.

In some embodiments, the coating layer 34 may wrap around or surround the base layer 31 and the reinforcement structure 32. In this case, step 1410 may be performed after step 920 of installing the reinforcement structure 32 and before step 930 of stacking the temporary layer 33. Alternatively, step 1410 may be performed after step 930, but in this case, the coating layer 34 may cover the temporary layer 33, which may require an additional process to remove the coating layer 34 formed on a top surface of the temporary layer 33 as needed.

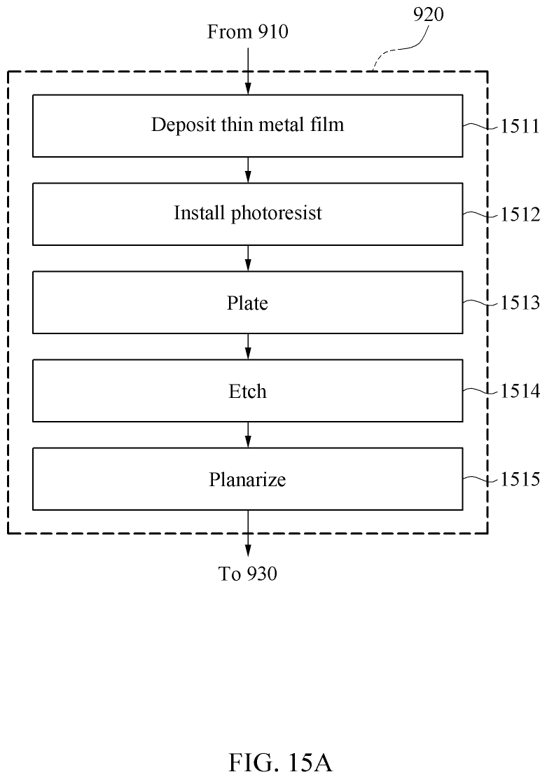

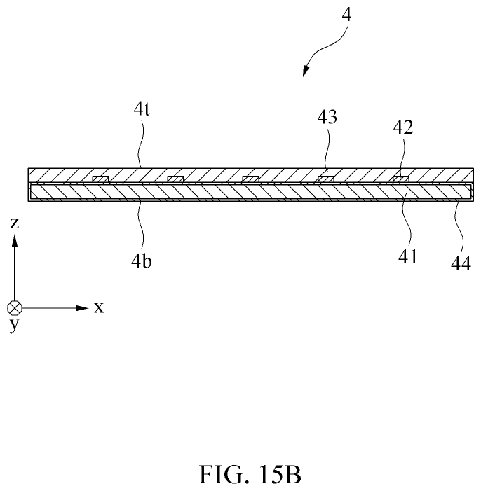

FIG. 15A is a flowchart illustrating a method of manufacturing a warpage compensation wafer according to some embodiments of the present disclosure, and FIG. 15B is a cross-sectional view of a warpage compensation wafer according to some embodiments of the present disclosure.

Referring to FIGS. 9A, 15A, and 15B, according to some embodiments of the present disclosure, a warpage compensation wafer 4 may include a base layer 41, a reinforcement structure 42, a temporary layer 43, and a coating layer 44. A top surface 4t of the warpage compensation wafer 4 may be the same as the top surface 4t of the temporary layer 43, and a bottom surface 4b of the warpage compensation wafer 4 may be the same as the bottom surface 4b of the coating layer 44. In this case, forming the bottom surface 4b of the coating layer 44 to be flat or planar may enable stable chucking onto a chuck apparatus among semiconductor measuring apparatuses.

In step 920 of installing a reinforcement structure, steps 1511 through 1515 shown in FIG. 15A may be performed. In step 1511, a PVD apparatus may deposit the coating layer 44 on an outer surface of the base layer 41 such that the coating layer 44 surrounds the base layer 41. For example, the coating layer 44 may be formed of a material (e.g., metal) having a lower etch rate than that of the base layer 41. By the coating layer 44, the extent to which the base layer 41 is etched during a process of separating the warpage compensation wafer 4 may be reduced, which may increase the number of times of reusing the warpage compensation wafer 4.

In step 1512, a photosensitive material may be coated on a top surface of the coating layer 44. In this case, an exposure process may be performed on the photosensitive material using a mask according to the shape of the designed reinforcement structure 42, and a development process may then be performed to form a photoresist according to the shape of the reinforcement structure 42.

In step 1513, a plating process may be performed on the coating layer 44 to form a metal layer according to the shape of the reinforcement structure 42. This may allow the coating layer 44 to protect the base layer 41 and to serve as a seed metal layer for forming the reinforcement structure 42. Therefore, there is no need to perform an additional process of forming the seed metal layer, which may reduce the cost and time required for the manufacturing processes.

In step 1514, an etching process may be performed to remove the photoresist. In step 1515, a CMP process may be performed to planarize the top surface of the formed reinforcement structure 42.

The coating layer 44 formed in steps 1511 through 1515 may cover the base layer 41, and the reinforcement structure 42 may be formed on the top surface of the coating layer 44.

While the example embodiments are described with reference to the accompanying drawings, it will be apparent to one of ordinary skill in the art that various alterations and modifications in form and details may be made in these embodiments without departing from the spirit and scope of the claims and their equivalents. For example, suitable results may be achieved if the described techniques are performed in a different order and/or if components in a described system, architecture, device, or circuit are combined in a different manner and/or replaced or supplemented by other components or their equivalents.

Therefore, other implementations, other embodiments, and equivalents to the claims are also within the scope of the following claims.

What is claimed is:

1. A semiconductor manufacturing method using at least one warpage compensation wafer comprising a first warpage compensation wafer comprising a first base layer having a flat bottom surface, a first reinforcement structure on a top surface of the first base layer, and a first temporary layer stacked on the first base layer and the first reinforcement structure, the semiconductor manufacturing method comprising:
chucking a bottom surface of the first warpage compensation wafer;
performing a first semiconductor manufacturing process directly on a top surface of the first temporary layer; and
separating the first warpage compensation wafer.

2. The semiconductor manufacturing method of claim 1, wherein the first semiconductor manufacturing process comprises:
a process of forming a semi-finished semiconductor product by deposition on the top surface of the first temporary layer.

3. The semiconductor manufacturing method of claim 1, wherein the first reinforcement structure is provided such that at least a portion of the first warpage compensation wafer has an anisotropic bending stiffness.

4. The semiconductor manufacturing method of claim 1, wherein the separating the first warpage compensation wafer comprises:
a process of etching the first temporary layer.

5. The semiconductor manufacturing method of claim 4, wherein the process of etching the first temporary layer is performed using an etchant having an etch rate for the first temporary layer that is higher than an etch rate for the first base layer.

6. The semiconductor manufacturing method of claim 1, further comprising:
determining whether a measured thickness of the separated first warpage compensation wafer or the first base layer is greater than or equal to a set thickness.

7. The semiconductor manufacturing method of claim 6, further comprising:
in response to the measured thickness being greater than or equal to the set thickness, stacking a new temporary layer on the separated first warpage compensation wafer.

8. The semiconductor manufacturing method of claim 6, further comprising:
in response to the measured thickness being less than the set thickness, increasing the thickness of the first base layer of the separated first warpage compensation wafer.

9. The semiconductor manufacturing method of claim 1, further comprising:
stacking a new temporary layer on the separated first warpage compensation wafer,
wherein the stacking the new temporary layer comprises:
depositing the same material as the temporary layer of the first warpage compensation wafer onto the separated first warpage compensation wafer; and
after the depositing, planarizing the new temporary layer,
wherein the depositing is performed until a thickness at all points of the new temporary layer becomes greater than or equal to a thickness of the temporary layer of a state before the first semiconductor manufacturing process.

10. The semiconductor manufacturing method of claim 2, wherein the at least one warpage compensation wafer comprises the first warpage compensation wafer and a second warpage compensation wafer,
wherein the second warpage compensation wafer comprises:
a second base layer having a flat bottom surface;
a second reinforcement structure on a top surface of the second base layer; and
a second temporary layer stacked on the second base layer and the second reinforcement structure,
the semiconductor manufacturing method further comprising:
chucking a bottom surface of the second warpage compensation wafer;
bonding the semi-finished semiconductor product onto a top surface of the second temporary layer;
performing a second semiconductor manufacturing process directly on a top surface of the semi-finished semiconductor product;
separating the second warpage compensation wafer;
before separating the first warpage compensation wafer, determining whether a warpage type according to the first semiconductor manufacturing process is the same as a warpage type according to the second semiconductor manufacturing process; and
in response to the warpage type according to the first semiconductor manufacturing process and the warpage type according to the second semiconductor manufacturing process being the same, performing the second semiconductor manufacturing process directly on the top surface of the semi-finished semiconductor product without replacing the first warpage compensation wafer with the second warpage compensation wafer.

11. The semiconductor manufacturing method of claim 10, wherein the warpage type is determined based on a warpage shape and a magnitude of deviation from a reference surface.

12. A method of manufacturing a warpage compensation wafer, the method comprising:
installing a reinforcement structure on a top surface of a base layer having a flat bottom surface to be chucked on a wafer chuck, the reinforcement structure having a material with a stiffness greater than that of a material of the base layer;
stacking a temporary layer covering at least a portion of a top of the base layer and a top of the reinforcement structure; and
planarizing a top surface of the temporary layer.

13. The method of claim 12, wherein the installing of the reinforcement structure comprises:
depositing, by a physical vapor deposition (PVD) apparatus, a thin metal film on the top surface of the base layer;
coating the thin metal film with a photosensitive material;
forming a photoresist by performing an exposure process on the photosensitive material using a mask and subsequently performing a development process;
forming a metal layer according to a shape of the reinforcement structure by performing a plating process in a state with the photoresist formed;
removing the photoresist by performing an etching process; and
planarizing a top surface of the reinforcement structure through a chemical mechanical polishing (CMP) process.

14. The method of claim 12, further comprising:
designing the reinforcement structure configured to compensate for warpage according to a warpage type,
wherein the designing the reinforcement structure comprises:
determining an axial direction of a bending moment inducing the warpage type and a magnitude of the bending moment;
determining an arrangement of the reinforcement structure, such that the reinforcement structure is formed to be elongated in a direction orthogonal to the axial direction of the bending moment; and
determining at least one of a number of reinforcement structures, a length of the reinforcement structure, a width of the reinforcement structure, or a height of the reinforcement structure to increase as the magnitude of the bending moment increases.

15. The method of claim 12, wherein the stiffness of the material of the reinforcement structure is greater than that of the material of the base layer by a factor of two or more times,
wherein the reinforcement structure allows at least a portion of the warpage compensation wafer disposed on the top surface of the base layer to have an anisotropic bending stiffness.

16. The method of claim 12, wherein a set etchant has an etch rate for the temporary layer that is higher than an etch rate for the base layer.

17. The method of claim 12, wherein the reinforcement structure has a shape that protrudes from the top surface of the base layer,
wherein a protruding portion of the temporary layer is inserted into a recess in an upper space of the base layer where the reinforcement structure is not installed to engage with the reinforcement structure.

18. The method of claim 12, further comprising:
forming a coating layer that covers at least a portion of the base layer and has a lower etch rate than the base layer with respect to a set etchant.

19. The method of claim 18, wherein the forming the coating layer is performed after the installing the reinforcement structure and before the stacking the temporary layer.

20. The method of claim 12, wherein the installing the reinforcement structure comprises:
depositing, by a physical vapor deposition (PVD) apparatus, a coating layer on an outer surface of the base layer to surround the base layer, with a material having a lower etch rate than that of the base layer;
forming a photoresist by coating a top surface of the coating layer with a photosensitive material, performing an exposure process on the photosensitive material using a mask, and subsequently performing a development process;
forming a metal layer according to a shape of the reinforcement structure by performing a plating process on the coating layer;
removing the photoresist by performing an etching process; and
planarizing a top surface of the reinforcement structure through a chemical mechanical polishing (CMP) process.
